(19) United States
(12) Patent Application Publication
(10) Pub. No.: US 2023/0324463 A1
(43) Pub. Date: Oct. 12, 2023

(54) Method and Apparatus for Operating a System for Detecting an Anomaly of an Electrical Energy Store for a Device by Means of Machine Learning Methods

(71) Applicant: Robert Bosch GmbH, Stuttgart (DE)

(72) Inventors: Christian Simonis, Leonberg (DE); Tobias Huelsing, Stuttgart (DE)

(21) Appl. No.: 18/190,548

(22) Filed: Mar. 27, 2023

(30) Foreign Application Priority Data
Apr. 5, 2022 (DE) 10 2022 203 343.4

(51) Int. Cl. G01R 31/367; G01R 31/3835

(52) U.S. Cl. CPC G01R 31/367; G01R 31/3835

(57) ABSTRACT

A computer-implemented method for determining an anomaly of a behavior of an electrical energy store in a technical device includes sensing an operating variable profile of at least one operating variable of the electrical energy store, and determining at least one feature from the sensed operating variable profile of the at least one operating variable of the electrical energy store. The method further includes evaluating an anomaly detection model using an autoencoder with a supplied input vector that includes or depends on the determined at least one feature, in order to determine a reconstructed input vector, and signaling an error based on a reconstruction error between the reconstructed input vector and the supplied input vector.

This application claims priority under 35 U.S.C. § 119 to patent application no. DE 10 2022 203 343.4, filed on Apr. 5, 2022 in Germany, the disclosure of which is incorporated herein by reference in its entirety.

The disclosure relates to network-independently operated, electrical devices with electrical energy stores, in particular to electrically drivable motor vehicles, in particular electric vehicles or hybrid vehicles, and furthermore to measures for detecting an anomaly of an electrical energy store.

### BACKGROUND

The supply of energy to network-independently operated, electrical devices and machines, such as electrically drivable motor vehicles, takes place by means of electrical energy stores, typically device batteries or vehicle batteries. The latter supply electrical energy for operating the devices. However, energy converters, such as fuel cell systems, including hydrogen tanks, also come into consideration as electrical energy stores.

Electrical energy stores or energy converters degrade over their service life and depending on their load or usage. This so-called aging leads to a continuously decreasing maximum power or storage capacity. The aging state corresponds to a measure for indicating the aging of energy stores. According to the convention, a new energy store has an aging state of 100%, the value of which decreases noticeably over the course of its service life. A lower value of the aging state thus indicates a higher degree of aging. The degree of aging of the energy store (change in the aging state over time) depends on an individual load on the energy store, i.e., in the case of vehicle batteries of motor vehicles, on the usage behavior of a driver, external ambient conditions and on the type of vehicle battery.

### SUMMARY

According to the disclosure, a method for determining an anomaly of the behavior of an electrical energy store as well as an apparatus for determining an anomaly of the behavior of an electrical energy store in an electrically operable device is provided.

According to a first aspect, a computer-implemented method for determining an anomaly of the behavior of an electrical energy store in a technical device is provided; comprising the following steps:
sensing an operating variable profile of the at least one operating variable of the electrical energy store;
determining at least one feature from the operating variable profile of the at least one operating variable of the electrical energy store;
evaluating an autoencoder with a supplied input vector that includes or depends on at least one of the features, in order to determine a reconstructed input vector;
signaling an error depending on a reconstruction error between the reconstructed input vector and the supplied input vector.

Energy stores within the meaning of this specification include device batteries, energy conversion systems with an electrochemical energy converter with an energy carrier supply, such as fuel cell systems with a fuel cell and an energy carrier supply.

In order to determine aging states, operating variables of energy stores in a plurality of devices are continuously sensed and evaluated in a central unit. According to the above method, it is furthermore possible to detect an anomaly of the energy store by additional evaluation based on the operating variable profiles in the central unit.

The aging state of an electrical energy store, in particular a device battery, is usually not measured directly. This would require a number of sensors inside the energy store, which would make the production of such an energy store costly, as well as complex, and would increase the space requirement. Moreover, measurement methods suitable for everyday use for direct determination of the aging state in the energy stores are not yet available on the market. The current aging state of an electrical energy store is therefore typically determined by means of a physical aging model in a central unit separate from the energy store.

Due to the inaccuracy of the physical aging model, it can moreover only somewhat accurately indicate the instantaneous aging state of the energy store. An aging state prediction, which in particular depends on the mode of operation of the energy store, such as the magnitude and amount of charge inflow and charge outflow in a device battery, and thus on usage behavior and usage parameters, would lead to very inaccurate predictions and is currently not provided.

In the case of device batteries, the aging state (state of health, SOH) is the key variable to indicate a remaining battery capacity or remaining battery charge. The aging state represents a measure of the aging of the device battery. In the case of a device battery or a battery module or a battery cell, the aging state may be indicated as a capacity retention rate (SOH-C). The capacity retention rate SOH-C is given as the ratio of the measured instantaneous capacity to an initial capacity of the fully charged battery. Alternatively, the aging state may be given as an increase in internal resistance (SOH-R) with respect to internal resistance at the start of the service life of the device battery. The relative change in the internal resistance SOH-R increases with increasing aging of the battery.

Promising are approaches to provide user-specific and usage-specific modeling and prediction of a load profile and the accompanying aging state of the electrical energy store based on an aging state model that uses the profiles of operating variables from the time of the initial operation to adjust the aging state, in each case, time step by time step, starting from the aging state at the time of the initial operation. This aging state model can be implemented purely based on data but also as a hybrid data-based aging state model. Such an aging state model may, for example, be implemented in a central unit (cloud) and are parameterized or trained by means of operating variables of a plurality of energy stores of various devices that are in communication connection with the central unit.

In a hybrid model, a physical aging state can be determined by means of a physical or electrochemical aging model, and a correction value resulting from a data-based correction model can be applied to said aging state, in particular by addition or multiplication. The physical aging model is based on electrochemical model equations that characterize electrochemical states of a non-linear differential equation system, calculate them continuously, and, for output, map them to the physical aging state, as SOH-C and/or as SOH-R. The calculations can typically be performed in the cloud, e.g., once a week.

Furthermore, the correction model of the hybrid data-based aging state model can be designed with a probabilistic or artificial intelligence-based data-based regression model, in particular a Gaussian process model, and can be trained to correct the aging state obtained by the physical aging model. For this purpose, there is consequently a data-based correction model of the aging state for correcting the SOH-C and/or at least one further model for correcting the SOH-R. Possible alternatives to the Gaussian process are further supervised learning methods, such as a random forest model, AdaBoost model, support vector machine, or a Bayesian neural network.

The correction model is designed to determine the correction variable based on operating features that are determined by feature extraction by signal processing from the profiles of the operating variables and can also comprise one or more of the internal electrochemical states of the differential equation system of the physical model. The operating features can comprise features relating to the evaluation period and/or accumulated features and/or statistical variables or aggregate variables determined over the entire previous service life.

The calculation of the physical/electrochemical model together with the correction model preferably takes place externally to the device since it is computationally intensive and the required processing power in the battery-operated devices or in hardware close to the battery-operated devices is often not sufficient or is not to be provided for cost reasons. The time profiles of the operating variables are therefore continuously transmitted to an external central unit, and the aging state is determined there according to the electrochemical model and, optionally, according to the correction model. Determining/training the data-based/hybrid aging state model usually takes place centrally in the central unit (cloud) for a plurality of energy stores of the same type based on the operating variable profiles and aging states of labels obtained by a field diagnostic measurement, in order to benefit from the network effect of the IoT energy stores, for example due to new labels. In this way, an aging state model is provided for all energy stores of the plurality of devices, which aging state model provides a current aging state depending on operating variable profiles of a corresponding energy store.

A plurality of operating features for each of the energy stores are available in the central unit for the evaluation of the aging state model in the central unit. The operating features are generated from the operating variable profiles and serve to determine, using the correction model, a correction variable for correcting the aging state modeled using the physical aging model. The operating features thereby characterize the load on the relevant energy store since their initial operation by cumulating or aggregating the load determined by the operating variable profiles.

According to the above method, features are used for anomaly detection. The operating features determined within the scope of determining the aging state are suitable for performing anomaly detection. As the at least one feature for the evaluation to determine an anomaly, at least one operating feature can be determined from the operating variable profile of the at least one operating variable of the electrical energy store as an aggregate variable.

While an erroneous behavior of the energy store or functional errors can only be detected early with difficulty and at high costs on the basis of the operating variable profiles, a determined abnormal load can be detected and signaled early as an anomalous behavior of the energy store on the basis of non-matching or abnormal characteristics of features, in particular operating features, specifically with respect to their combination.

In principle, the autoencoder can be trained using training data sets, wherein the training data sets are formed with the at least one feature from respectively proper energy stores.

The autoencoder is trained, in particular in an unsupervised manner, even during ongoing application of the above method, in particular using feature points of a plurality of energy stores that operate flawlessly. Assuming that a majority of the operating feature points thus considered belong to proper energy stores, such training of the anomaly detection model is permitted.

For example, an autoencoder may be trained and provided as an anomaly detection model based on operating feature points of the large number of energy stores. Thus, an anomaly of a device battery can be determined based on detection and evaluation of a reconstruction error. For this purpose, at the same time as determining the current aging state by means of the hybrid aging state model, the operating features of the relevant device battery may, for example, be used to perform anomaly detection.

It may be provided in addition to the autoencoder that a load-state vector is determined from the operating features using a main component analysis (PCA) or a kernel main component analysis (kernel PCA), wherein the autoencoder is trained with the load-state vectors of a plurality of energy stores, wherein the load-state vector is evaluated as the supplied input vector in the autoencoder. The main component analysis (PCA) is used to eliminate redundant information.

Since an autoencoder based on all operating features used for the correction model can become very complex, the operating features of the operating feature points can thus, for example, be transformed into a smaller state space using a main component analysis (PCA) in order to provide a load-state vector. While the correction model can be trained on the load-state vectors rather than on the operating features, it is also possible to train the autoencoder on load-state vectors of all energy stores of the plurality of devices in order to use it for anomaly detection. The main component transformation can be dimensioned in such a way that, for example, at least 99% of the variance can be explained with regard to the original feature distribution, even in the transformed state. The main component transformation is thus used exclusively to remove redundant information in the feature space.

Alternatively or additionally, at least one error feature can be determined as the at least one feature, wherein the error feature results from statistically evaluating a difference between a variable modeled in particular using a battery performance model and a measured variable for a predetermined time interval, wherein in particular a difference between a modeled battery voltage and a measured battery voltage is evaluated.

In particular, the evaluation may comprise a residual analysis comprising a determination of a mean value and a measure of dispersion of the difference values.

An anomaly can be detected with the autoencoder by evaluating a reconstruction error. In particular, an anomaly can be detected if a reconstruction error is detected that is greater than a predetermined error threshold value.

A detected anomaly in one of the energy stores can be appropriately signaled by the central unit, e.g., by a monitoring tool, by a mobile device, or the like. For example, a warning message may be output to a user of the relevant device operated with the energy store.

Furthermore, the reconstruction error can be compared to a first error threshold value in order to signal a warning of a possible malfunction of the energy store if the reconstruction error exceeds the first error threshold value.

Alternatively or additionally, the reconstruction error can be compared to a second, higher error threshold value in order to signal an error of the energy store if the reconstruction error exceeds the second error threshold value.

In order to determine the first and/or the second error threshold value, a statistical evaluation of the reconstruction errors of training data sets, which have been used by proper energy stores for training the autoencoder, can be performed, wherein the first or the second error threshold value is selected, in particular as the maximally occurring reconstruction error, depending on the distribution of the reconstruction errors resulting from the evaluation of the training data sets using the trained autoencoder.

The warning message can thus depend on the level of a reconstruction error. For example, upon reaching a first error threshold value, an indication of a possible anomaly can be output and upon reaching a second error threshold value, an actual error can be signaled.

The energy store may be used to operate a device, such as a motor vehicle, a pedelec, an aircraft, in particular a drone, a machine tool, a consumer electronics device, such as a mobile phone, an autonomous robot, and/or a household appliance.

According to a further aspect, an apparatus for determining an anomaly of the behavior of an electrical energy store in a technical device is; wherein the apparatus is designed for:
sensing an operating variable profile of the at least one operating variable of the electrical energy store;
determining operating features from the operating variable profile of the at least one operating variable of the electrical energy store as aggregated variables;
evaluating an autoencoder with a supplied input vector that includes or depends on the operating features, in order to determine a reconstructed input vector;
signaling an error depending on a reconstruction error between the reconstructed input vector and the supplied input vector.

### BRIEF DESCRIPTION OF THE DRAWINGS

Embodiments are explained in more detail below with reference to the accompanying drawings. Shown are:

FIG. 1 a schematic illustration of a system for providing driver-specific and vehicle-specific operating variables for determining an aging state of a vehicle battery in a central unit;

FIG. 2 a schematic illustration of a functional structure of a system comprising an anomaly detection model and a hybrid aging state model; and

FIG. 3 a flow chart illustrating a method for determining an anomaly of the behavior of an electrical energy store.

### DETAILED DESCRIPTION

In the following, the method according to the disclosure is described with reference to vehicle batteries as electrical energy stores in a plurality of motor vehicles as similar devices. In the motor vehicles, a data-based aging state model for the respective vehicle battery can be implemented in a control unit. As described below, the aging state model can be continuously updated or re-trained in an off-board central unit based on operating variables of the vehicle batteries from the vehicle fleet. The aging state model is operated in the central unit and used for aging calculation and aging prediction.

The above example is representative of a plurality of stationary or mobile devices with a network-independent energy supply, such as vehicles (electric vehicles, pedelecs, etc.), systems, machine tools, household appliances, IOT devices, and the like, which are connected via a corresponding communication connection (e.g., LAN, Internet) to an external central unit (cloud).

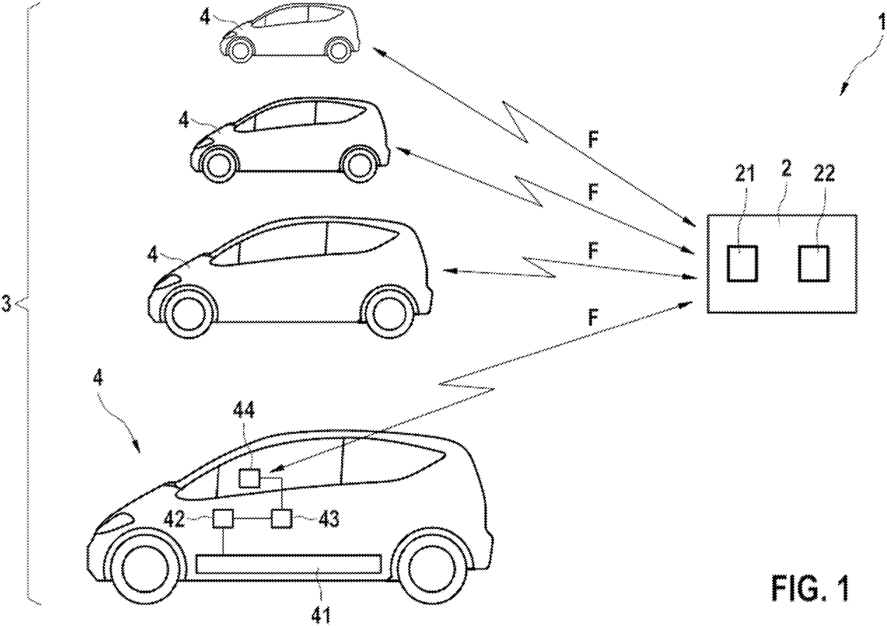

FIG. 1 shows a system 1 for collecting fleet data in a central unit 2 for creating and for operating as well as for evaluating an aging state model. The aging state model is used to determine an aging state of an electrical energy store, such as a vehicle battery or a fuel cell in a motor vehicle. FIG. 1 shows a vehicle fleet 3 with several motor vehicles 4.

One of the motor vehicles 4 is shown in more detail in FIG. 1. The motor vehicles 4 each comprise a vehicle battery 41 as a rechargeable electrical energy store, an electric drive motor 42 and a control unit 43. The control unit 43 is connected to a communication module 44, which is suitable for transmitting data between the respective motor vehicle 4 and a central unit 2 (a so-called cloud).

The motor vehicles 4 send to the central unit 2 the operating variables F, which indicate at least variables that influence the aging state of the vehicle battery 41. In the case of a vehicle battery, the operating variables F can indicate an instantaneous battery current, an instantaneous battery voltage, an instantaneous battery temperature and an instantaneous state of charge (SOC), at the pack, module and/or cell level. The operating variables F are sensed in a fast time grid from 0.1 Hz to 100 Hz and can be transmitted regularly to the central unit 2 in uncompressed and/or compressed form. For example, by using compression algorithms, the time series may be transmitted to the central unit 2 in blocks at intervals of 10 min to several hours in order to minimize the data traffic to the central unit 2.

The central unit 2 comprises a data processing unit 21, in which the method described below can be performed, and a database 22 for storing data points, model parameters, states, and the like.

In the central unit 2, an aging state model is implemented, which, as a hybrid model, is partially data-based. The aging state model may be used regularly, i.e., for example, after the respective evaluation period has elapsed, in order to determine the instantaneous aging state of the relevant vehicle battery 41 of the associated vehicle fleet based on the time profiles of the operating variables (in each case since the initial operation of the respective vehicle battery) and operating features determined therefrom. In other words, it is possible to determine an aging state of the relevant vehicle battery 41 based on the profiles of the operating variables of one of the vehicle batteries 41 of the motor vehicles 4 of the associated vehicle fleet 3 and the operating features resulting from these profiles of the operating variables.

The aging state (state of health, SOH) is the key variable to indicate a remaining battery capacity or remaining battery charge. The aging state represents a measure of the aging of the vehicle battery or of a battery module or of a battery cell and may be indicated as a capacity retention rate (SOH-C) or as an increase in internal resistance (SOH-R). The capacity retention rate SOH-C is given as the ratio of the measured instantaneous capacity to an initial capacity of the fully charged battery. The relative change in the internal resistance SOH-R increases with increasing aging of the battery.

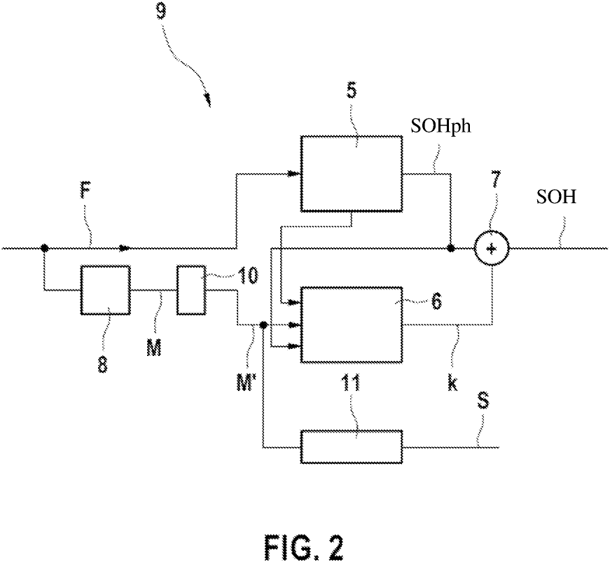

FIG. 2 schematically shows, by way of example, the functional structure of an embodiment of a data-based aging state model 9 structured in a hybrid manner. The aging state model 9 comprises a physical aging model 5 and a data-driven, preferably probabilistic, correction model 6.

The physical aging model 5 is a non-linear mathematical model based on differential equations. The evaluation of the physical aging model of the aging state model with operating variable profiles, in particular since the start of the service life of the device battery, results in an internal state of the equation system of the physical differential equations that corresponds to a physical internal state of the device battery. Since the physical aging model is based on physical and electrochemical principles, the model parameters of the physical aging model are variables that indicate physical properties.

The time series of the operating variables F are thus directly included in the physical aging state model 5, which is preferably designed as an electrochemical model and describes corresponding internal electrochemical states, such as layer thicknesses (e.g., SEI thickness), change in cyclable lithium due to anode/cathode side reactions, rapid consumption of electrolytes, slow consumption of electrolytes, loss of active material in anode, loss of active material in cathode, etc....), by means of non-linear differential equations and a multi-dimensional state vector.

The physical aging model 5 thus corresponds to an electrochemical model of the battery cells and of the cell chemistry. This model determines, depending on the operating variables F, internal physical battery states in order to provide a physically based aging state SOHph of the dimension of at least one in the form of the electrochemical states mentioned above, which are mapped linearly or non-linearly to a capacity retention rate (SOH-C) and/or an internal resistance increase rate (SOH-R) in order to provide the later as an aging state (SOH-C and SOH-R).

However, the model values for the physical aging state SOHph provided by the electrochemical model are inaccurate in certain situations and it is therefore provided to correct them with a correction variable k. The correction variable k is provided by the data-based correction model 6, which is trained by means of training data sets from the vehicles 4 of the vehicle fleet 3 and/or by means of laboratory data.

On the input side, the correction model 6 receives operating features M, which can be determined by feature extraction (feature engineering) from the profiles of the operating variables F and can also comprise one or more of the internal electrochemical states of the differential equation system of the physical model. Furthermore, the correction model 6 may receive on the input side the physical aging state SOHph obtained from the physical aging model 5. The operating features M of the current evaluation period are generated in a feature extraction block 8 based on the time series of the operating variables F. The operating features M furthermore include the internal states from the state vector of the electrochemical physical aging model as well as, advantageously, the physical aging state SOHph.

From the operating variables F, operating features M relating to an evaluation period can be generated in the central unit 2 for each vehicle fleet 3 or in other embodiments even already in the respective motor vehicles 4. The evaluation period for determining the aging state may be a few hours (e.g., 6 hours) to several weeks (e.g., one month). A typical value for the evaluation period is one week.

The operating features M may, for example, comprise features relating to the evaluation period and/or accumulated features and/or statistical variables or aggregate variables determined over the entire previous service life. In particular, the operating features may comprise, for example: electrochemical states, such as SEI layer thickness, mass or quantity change of cyclable lithium due to anode/cathode side reactions, rapid absorption of electrolyte solvent, slow absorption of electrolyte solvents, lithium deposition, loss of active anode material and loss of active cathode material, information on impedances or the internal resistances, histogram features, such as temperature over state of charge, charging current over temperature and discharging current over temperature, in particular multi-dimensional histogram data with respect to the battery temperature distribution over the state of charge, the charging current distribution over the temperature and/or the discharging current distribution over the temperature, the current flow rate in ampere-hours, the accumulated total charge (Ah), an average increase in capacity during a charging process (in particular for charging processes in which the charge increase is above a threshold fraction [e.g., 20% ΔSOC] of the total battery capacity), the charging capacity as well as an extreme value (e.g., maximum) of the differential capacity during a measured charging process with sufficiently large stroke of the state of charge (smoothed profile of dQ/dU: charge change divided by change in the battery voltage) or the accumulated driving power. These variables are preferably converted such that they optimally characterize the actual usage behavior and are normalized in the feature space. The operating features M may be used altogether or only in part for the method described below.

For the determination of a corrected aging state SOH to be output, the outputs SOHph, k of the physical aging model 5 and of the data-based correction model 6, which is preferably designed as a Gaussian process model, are applied together. In particular, they can be added in a summing block 7 or otherwise also multiplied (not shown) in order to obtain the modeled aging state SOH to be output for a current evaluation period. The confidence of the Gaussian process can furthermore be used in the case of addition as the confidence of the corrected aging value SOH of the hybrid model to be output. The confidence of the Gauss process model thus characterizes the modeling uncertainty of the mapping of operating feature points or of main components (when using PCA) to an aging state.

For the scaling and dimension reduction of the operating features, a PCA (principal components analysis) can optionally be used in a PCA block 10 in order to appropriately reduce redundant linear-dependent information in the feature space prior to training the correction model (in an unsupervised manner). The main component transformation is dimensioned in such a way that, for example, at least 99% of the variance can be explained with regard to the original feature distribution, even in the transformed state. In the PCA block 10, a load-state vector M′ is determined from the operating features of an operating feature point to be evaluated.

Alternatively, a kernel PCA may also be used in order to be able to map even non-linear effects in the complexity reduction of the data. Both prior to the reduction in dimension and especially thereafter, normalization of the entire operating feature space (or of the main component space) takes place, e.g., with min/max scaling or Z transformation.

For training the correction model, aging states are determined as labels in a manner known per se, by evaluating the operating variable profiles with an additional model under defined load and environmental conditions, such as in a workshop, on a test rig. For this purpose, other models may be used to determine the aging state, e.g., based on the analysis of a detected charging and/or discharging phases of battery usage. Preferably, an SOH-C measurement is carried out by Coulomb counting or by forming a time integral of the current during the charging process, which is divided by the stroke of the state of charge between the start and end of the respective charging and/or discharging phase.

The aging state model can be trained in a conventional manner. For this purpose, it is provided that the training of the correction model 6 takes place on the residual of the physical aging model so that the correction model can accordingly carry out data-driven corrections exactly where the data situation allows it with sufficient confidence.

An anomaly detection model 11, to which is supplied the operating feature point M and/or, as shown in FIG. 2, the load-state vector M′, can be provided for anomaly detection. The anomaly detection model 11 can comprise an autoencoder. The autoencoder is preferably evaluated by evaluating a reconstruction error, in particular by a threshold comparison. As a result of the threshold comparison, an error signal S is output.

In addition to one or more of the operating features M, which may already result from the implementation of the hybrid aging state model, or optionally the load-state vector M′, at least one error feature can also be used for the evaluation in the anomaly detection model 11.

A possible error feature evaluates or indicates a difference in the voltage response of a battery voltage modeled by an electrochemical battery performance model and an actually measured battery voltage. This signal processing step can be included in the feature extraction block 8. Preferred here is the battery performance model, which may, e.g., be designed as an electrochemical performance model or a fractional performance model and is implemented embedded or via edge computing, wherein the model parameters of the battery performance model can be adjusted via an observer and/or additionally as a function of the hybrid aging model.

The at least one error feature can be determined by evaluating for a defined time interval, such as within the past 5 to 10 days, the residual of at least one battery cell or one battery module or one battery pack, i.e., the difference of the voltage response of a battery voltage modeled by the electromechanical battery performance model and the actually measured battery voltage. For this purpose, battery voltages can be modeled based on the battery current sampled at short time intervals (0.1 to 1 Hz), and the difference for the battery voltages sensed at the respective time points can be calculated. The differences can be evaluated statistically. Preferably, the expected value of this residual, i.e., the average difference, as well as a measure of dispersion, e.g., the standard deviation, and further statistical variables, such as minimum, maximum, as well as moments of distribution, can be used as features, which can represent error features for the autoencoder.

Another error feature may arise, for example, from the difference in the amount of cyclable lithium determined in two different ways. The amount of cyclable lithium can be determined from an electrochemical aging state model that physically tracks the state of the energy store by a time integration method. Furthermore, based on an electrochemical battery performance model adjusted by actual measurements, the amount of the cyclable lithium can be determined depending on a voltage response. The battery performance model can be designed in a manner known per se, in order to map load variables, such as a battery current and a battery temperature, to a battery voltage.

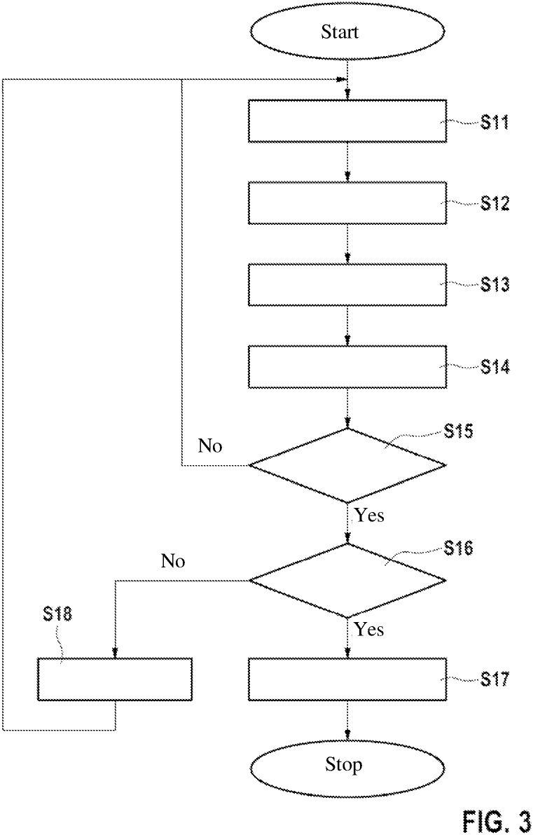

FIG. 3 shows a flow chart illustrating a method for anomaly detection of the behavior of vehicle batteries 41 as an example of energy stores of vehicles 4 of a vehicle fleet 3 (corresponding to the devices of the plurality of devices). The method is performed in the central unit 2. The usual execution frequency of the method is battery-specific and may correspond to a weekly execution as a standard case when no acute anomaly is suspected.

In step S11, a conventional operation of the hybrid aging model of the central unit 2 takes place. In ongoing operation, continuous profiles of operating variables F, such as the battery current, the battery voltage, the state of charge and the battery temperature, are transmitted from each of the vehicles 4 of the vehicle fleet 3 to the central unit 2. The error feature determined as described above may be determined in both the vehicle 4 and the central unit 2.

In step S12, the operating variable profiles are evaluated at predetermined times in order to determine an aging state for each of the relevant device batteries. For this purpose, a physical aging state SOHph is directly determined from the operating variable profiles by the physical aging model 5 and operating features M are updated or determined as described above.

Furthermore, in step S13, the operating features are further processed for evaluation in the correction model using a PCA in the PCA block 10 in order to reduce the state space of the operating features and to obtain the load-state vector M′ for the relevant vehicle battery 41.

One or more operating features M and/or the load-state vector M′ and/or the at least one error feature can serve as an input vector for the correction model 6. The one or more operating features M In step S14, the load-state vector M′ is furthermore supplied as anomaly detection model 11 to an autoencoder, which has been trained with load-state vectors M′ of the plurality of vehicle batteries 41 in past evaluation cycles.

In a manner known per se, the autoencoder maps its input vector with features to itself and thereby generates a dimension-reduced state vector representing characteristic features of the input vector, namely of the operating feature point from the one or more operating features and/or, when using the PCA, the load-state vector and/or the at least one error feature. The autoencoder can preferably be further trained after each new determination of the input vector.

A reconstruction error can be determined by evaluating the autoencoder with the load-state vector M′ of each of the relevant vehicle batteries 41 to be evaluated. The reconstruction error corresponds to a measure of a deviation between the reconstructed input vector and the supplied input vector.

In step S15, the measure of deviation is compared to a predetermined first error threshold value by a threshold comparison and it is determined thereby whether the reconstruction error exceeds the first error threshold value. If it is determined that the reconstruction error exceeds the first error threshold value (alternative: Yes), the method is continued with step S16. Otherwise (alternative: No), a jump back to step S11 occurs.

In step S16, the measure of deviation is compared to a predetermined second error threshold value in a threshold comparison. If it is determined that the reconstruction error exceeds the second error threshold value (alternative: Yes), an error of the vehicle battery 41 is signaled in step S17. Moreover, the execution frequency can be set to a maximum execution frequency in order to track the evolution of the error.

Otherwise (alternative: no), the method is continued with step S18.

In addition to the training of the autoencoder, a statistical evaluation of the reconstruction errors of the training data used to train the autoencoder, e.g., by a clustering method, may also take place in order to determine the first and/or the second error threshold value. For example, the second error threshold value may be selected to correspond to the maximum reconstruction error of all proper vehicle batteries 41. In reality, the interpretation of the second error threshold value for anomaly detection can take place on the basis of the false-positive error determined purely on the basis of proper vehicle batteries. The first error threshold value can result as a predetermined fraction of the second error threshold value so that the first error threshold value is less than the second error threshold value.

In step S18, a warning is signaled that the relevant vehicle battery 41 may have an error. Depending on the reconstruction error, which represents a measure of the severity of the anomaly, a rule-based measure is initiated, e.g., automated shutdown of the vehicle or transfer of the battery into a safe state, e.g., via rapid discharge, in the case of high probability and high severity or, e.g., planning a workshop visit for inspection of the sensor system in the case of low probability and medium severity.

Moreover, the execution frequency of the method for determining the anomaly of the electrical energy store can be adjusted to a more frequent value (such as daily), in particular as a function of the reconstruction error.

The evaluation with regard to a detection of an anomaly may be performed regularly and in particular simultaneously with the determination of the aging state by means of the hybrid aging state model 9 since at this time, the operating feature points M required for the correction model 6 or the load-state vectors are determined from the newly sensed operating variable profiles.

What is claimed is:

1. A computer-implemented method for determining an anomaly of a behavior of an electrical energy store in a technical device comprising:
sensing an operating variable profile of at least one operating variable of the electrical energy store;
determining at least one feature from the sensed operating variable profile of the at least one operating variable of the electrical energy store;
evaluating an anomaly detection model using an autoencoder with a supplied input vector that includes or depends on the determined at least one feature, in order to determine a reconstructed input vector; and
signaling an error based on a reconstruction error between the reconstructed input vector and the supplied input vector.

2. The method according to claim 1, wherein determining the at least one feature comprises:
determining at least one operating feature from the sensed operating variable profile of the at least one operating variable of the electrical energy store as an aggregate variable.

3. The method according to claim 2, wherein determining the at least one feature comprises:
determining a load-state vector from the determined at least one operating feature using a main component analysis or a kernel main component analysis,
wherein the autoencoder is trained with the load-state vectors from a plurality of the electrical energy stores, and
wherein the load-state vector is evaluated as a supplied input vector in the autoencoder.

4. The method according to claim 1, wherein determining the at least one feature comprises:
determining at least one error feature resulting from a statistical evaluation of a difference between a variable modeled using a battery performance model and a variable determined or measured by a further method or model for a predetermined time interval; and
evaluating a difference between a modeled battery voltage and a measured battery voltage and/or a difference between an amount of cyclable lithium modeled using the battery performance model and an amount of cyclable lithium resulting from an evaluation of an operating variable profile using a physical aging state model.

5. The method according to claim 1, further comprising:
comparing the reconstruction error to a first error threshold value in order to signal a warning of a possible malfunction of the electrical energy store when the reconstruction error exceeds the first error threshold value.

6. The method according to claim 5, further comprising:
comparing the reconstruction error to a second, higher error threshold value in order to signal the error of the energy store when the reconstruction error exceeds the second error threshold value.

7. The method according to claim 6, further comprising:
performing a statistical evaluation of the reconstruction errors of training data sets, which have been used by proper energy stores for training the autoencoder; and
selecting the first or the second error threshold value as the maximally occurring reconstruction error, based on a distribution of the reconstruction errors resulting from the evaluation of the training data sets using the trained autoencoder.

8. The method according to claim 1, further comprising:
selecting an energy store-specific execution frequency of the method based on the reconstruction error.

9. The method according to claim 1, further comprising:
training the autoencoder using training data sets formed by respectively proper electrical energy stores.

10. The method according to claim 3, further comprising:
providing an aging state model that uses the at least one operating feature or the load-state vector to determine an aging state in a data-based model.

11. The method according to claim 1, wherein signaling the error comprises:
automatically shutting down the technical device, transferring the electrical energy store into a safe state via rapid discharge, or planning of a workshop visit for inspection of the technical device or the electrical energy store.

12. The method according to claim 1, wherein:
the electrical energy store is used to operate the technical device, and
the technical device is a motor vehicle, a pedelec, an aircraft, a drone, a machine tool, a consumer electronics device, a mobile phone, an autonomous robot, or a household appliance.

13. The method according to claim 1, wherein a computer program product comprises instructions that, when the computer program product is executed by at least one data processing device, causes the at least one data processing device to perform the method.

14. The method according to claim 13, wherein the computer program product is stored on a non-transitory machine-readable storage medium.

15. An apparatus for determining an anomaly of a behavior of an electrical energy store in a technical device, the apparatus comprising:
a control unit configured to:
sense an operating variable profile of at least one operating variable of the electrical energy store;
determine at least one feature from the sensed operating variable profile of the at least one operating variable of the electrical energy store;
evaluate an anomaly detection model using an autoencoder with a supplied input vector that includes or depends on the determined at least one feature, in order to determine a reconstructed input vector; and
signal an error based on a reconstruction error between the reconstructed input vector and the supplied input vector.
